(19) United States
(12) Patent Application Publication
(10) Pub. No.: US 2025/0221256 A1
(43) Pub. Date: Jul. 3, 2025

(54) DISPLAY DEVICE

(71) Applicant: LG Display Co., Ltd., Seoul (KR)

(72) Inventor: Choonghyo KIM, Paju-si (KR)

(21) Appl. No.: 18/789,359

(22) Filed: Jul. 30, 2024

(30) Foreign Application Priority Data
Dec. 28, 2023 (KR) 10-2023-0195713

(51) Int. Cl. H10K 59/80; H10K 59/121; H10K 59/122; H10K 59/131; H10K 59/38; H10K 102/00

(52) U.S. Cl. CPC H10K 59/873; H10K 59/1213; H10K 59/1216; H10K 59/122; H10K 59/131; H10K 59/38; H10K 59/8792; H10K 2102/3026

(57) ABSTRACT

A display device according to an example embodiment of the present disclosure includes a substrate including a plurality of sub-pixels, an encapsulation substrate bonded to the substrate in a state where an adhesive film is disposed on the substrate, a driving transistor disposed in the sub-pixel, an organic light emitting diode connected to the driving transistor, a cathode contact part connected to the organic light emitting diode and configured to apply a low-potential voltage, a first gap structure disposed over the cathode contact part, and a second gap structure disposed over the encapsulation substrate so as to face the first gap structure. Thus, a uniform cell gap can be maintained during a bonding process. Therefore, it is possible to suppress a pressing dark spot caused by foreign matter generated inside the display device.

### CROSS-REFERENCE TO RELATED APPLICATIONS

This application claims the priority of Korean Patent Application No. 10-2023-0195713 filed on Dec. 28, 2023, in the Korean Intellectual Property Office, the disclosure of which is incorporated herein by reference.

### BACKGROUND

### Technical Field

The present disclosure relates to a display device, and more particularly, to a top emission display device.

### Description of the Related Art

Organic light emitting display devices are self-luminous display devices and do not require a separate light source unlike liquid crystal display devices. Thus, the organic light emitting display devices can be manufactured lightly and thin. Further, the organic light emitting display devices are not only advantageous in terms of power consumption by low voltage driving, but also has excellent response speed, viewing angle, and contrast ratio.

Attempts have been made to manufacture such an organic light emitting display device as a transparent organic light emitting display device, which is a transparent display device. A pixel area of the transparent organic light emitting display is divided into an emission area in which an organic light emitting diode emits light to display an image, and a transmission area which transmits external light. Transparency of the transparent organic light emitting display device is secured through the transmission area.

### BRIEF SUMMARY

The present disclosure provides a display device capable of suppressing a dark spot by pressing (hereinafter, referred to as “pressing dark spot”) caused by foreign matter generated inside the display device by maintaining a cell gap during a bonding process.

The present disclosure provides a display device capable of suppressing the propagation of a crack occurring in a protection layer during a bonding process.

The present disclosure provides a display device capable of maintaining a uniform cell gap.

Technical characteristics and features of the present disclosure are not limited to those mentioned above, and other technical characteristics and features, which are not mentioned above, can be clearly understood by those skilled in the art from the following descriptions.

A display device according to an example embodiment of the present disclosure includes a substrate in which a plurality of sub-pixels is defined, an encapsulation substrate bonded to the substrate with an adhesive film interposed therebetween, a driving transistor disposed in the sub-pixel, an organic light emitting diode connected to the driving transistor, a cathode contact part connected to the organic light emitting diode and configured to apply a low potential voltage, a first gap structure disposed over the cathode contact part and a second gap structure disposed over the encapsulation substrate so as to face the first gap structure.

Other detailed matters of the example embodiments are included in the detailed description and the drawings.

According to the present disclosure, a first gap structure composed of an overcoating layer and a bank layer having an island shape is provided on a cathode contact part. A second gap structure in which a black matrix and a color filter are deposited is provided on the first gap structure. Thus, a uniform cell gap can be maintained during a bonding process. Therefore, it is possible to suppress a pressing dark spot caused by foreign matter generated inside a display device.

According to the present disclosure, an undercut structure is provided under the first gap structure. Therefore, it is possible to suppress the propagation of a crack occurring in a protection layer during the bonding process and thus possible to improve reliability.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a block diagram for explaining a display device according to example embodiments of the present disclosure;

FIG. 2 is a schematic circuit diagram of a sub-pixel according to example embodiments of the present disclosure;

FIG. 3 is a detailed circuit diagram of the sub-pixel according to example embodiments of the present disclosure;

FIG. 4 is a plan view of a display device according to First Example of the present disclosure;

FIG. 5 is an enlarged view of an area C of FIG. 4;

FIG. 6 is a cross-sectional view taken along a line A-A′ and a line B-B′ of FIG. 5;

FIG. 7 is a cross-sectional view of a display device according to Second Example of the present disclosure;

FIG. 8 is a cross-sectional view of a display device according to Third Example of the present disclosure;

FIG. 9 is a cross-sectional view of a display device according to Fourth Example of the present disclosure;

FIG. 10 is a cross-sectional view of a display device according to Fifth Example of the present disclosure;

FIG. 11 is a cross-sectional view of a display device according to Sixth Example of the present disclosure;

FIG. 12 is a plan view of a display device according to Seventh Example of the present disclosure;

FIG. 13 is a cross-sectional view taken along a line D-D′ and a line E-E′ of FIG. 12; and

FIG. 14 is a cross-sectional view of a display device according to Eighth Example of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an example embodiment of the present disclosure will be described in detail with reference to the drawings.

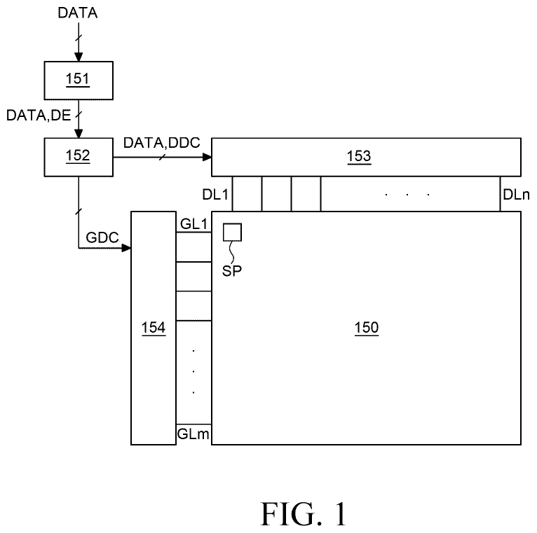

FIG. 1 is a block diagram for explaining a display device according to example embodiments of the present disclosure.

Referring to FIG. 1, the display device according to example embodiments of the present disclosure may include an image processor 151, a timing controller 152, a data driver 153, a scan driver 154, and a display panel 150.

The image processor 151 may output a data enable signal DE together with a data signal DATA supplied from the outside.

The timing controller 152 may receive the data signal DATA and driving signals including the data enable signal DE or a vertical sync signal, a horizontal sync signal, a clock signal, etc., from the image processor 151. The timing controller 152 may output a gate timing control signal GDC for controlling operation timing of the scan driver 154 and a data timing control signal DDC for controlling operation timing of the data driver 153 based on the driving signals.

The data driver 153 may sample and latch the data signal DATA received from the timing controller 152 in response to the data timing control signal DDC received from the timing controller 152. Also, the data driver 153 may convert the sampled and latched data signal DATA into a gamma reference voltage. The data driver 153 may output the data signal DATA through data lines DL1 to DLn.

Also, the scan driver 154 may output a scan signal in response to the gate timing control signal GDC received from the timing controller 152. The scan driver 154 may output the scan signal through gate lines GL1 to GLm.

The display panel 150 may display an image in response to the data signal DATA and the scan signal respectively received from the data driver 153 and the scan driver 154.

The display panel 150 may include a plurality of sub-pixels SP to display an image.

For example, the sub-pixels SP may include a red sub-pixel, a green sub-pixel, and a blue sub-pixel, or may include a white sub-pixel, a red sub-pixel, a green sub-pixel, and a blue sub-pixel. Further, the sub-pixels SP may have one or more different emission areas depending on emission characteristics.

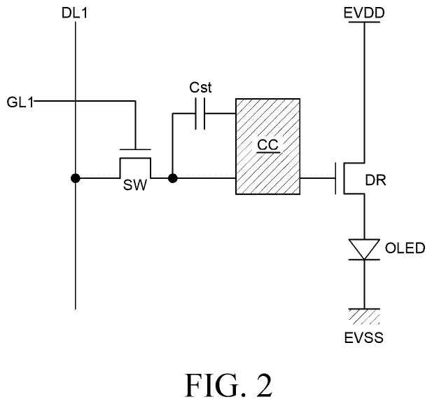

FIG. 2 is a schematic circuit diagram of a sub-pixel according to example embodiments of the present disclosure.

Referring to FIG. 2, each sub-pixel may include a switching transistor SW, a driving transistor DR, a capacitor Cst, a compensation circuit CC, and an organic light emitting diode OLED.

The switching transistor SW performs a switching operation so that a data signal supplied through a data line DL is stored in the capacitor Cst as a data voltage in response to a scan signal supplied through a first gate line GL1. The driving transistor DR enables a driving current to flow between a power line EVDD (high-potential voltage) and a cathode power line EVSS (low-potential voltage) based on the data voltage stored in the capacitor Cst. The organic light emitting diode OLED may emit light depending on the driving current generated by the driving transistor DR.

The compensation circuit CC is a circuit added to the sub-pixel and compensates for a threshold voltage of the driving transistor DR. The compensation circuit CC includes one or more transistors. A configuration of the compensation circuit CC may be variously changed depending on an external compensation method and will be described below.

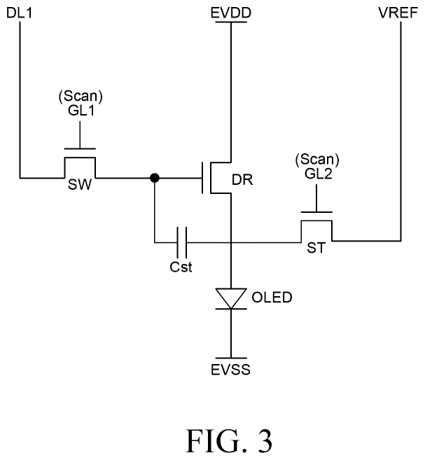

FIG. 3 is a detailed circuit diagram of the sub-pixel according to example embodiments of the present disclosure.

Referring to FIG. 3, the compensation circuit CC may include, for example, a sensing transistor ST and a sensing line (or a reference line) VREF.

Herein, the sensing transistor ST is connected between a source electrode of the driving transistor DR and an anode of the organic light emitting diode OLED (hereinafter, referred to as “sensing node”). The sensing transistor ST may operate to supply an initialization voltage (or sensing voltage) transferred through the sensing line VREF to the sensing node of the driving transistor DR. Also, the sensing transistor ST may operate to sense a voltage or current of the sensing node or sensing line VREF of the driving transistor DR.

A source electrode or drain electrode of the switching transistor SW may be connected to the data line DL. The other one of the source electrode and the drain electrode of the switching transistor SW may be connected to a gate electrode of the driving transistor DR.

A source electrode or drain electrode of the driving transistor DR may be connected to the power line EVDD. The other one of the source electrode and the drain electrode of the driving transistor DR may be connected to a first electrode, which is the anode, of the organic light emitting diode OLED.

Further, a lower electrode of the capacitor Cst may be connected to the gate electrode of the driving transistor DR, and an upper electrode of the capacitor Cst may be connected to the anode of the organic light emitting diode OLED. The first electrode of the organic light emitting diode OLED may be connected to the other one of the source electrode and the drain electrode of the driving transistor DR. Also, a second electrode, which is a cathode, of the organic light emitting diode OLED may be connected to the second power line EVSS.

A source electrode or drain electrode of the sensing transistor ST may be connected to the sensing line VREF. The other one of the source electrode and the drain electrode of the sensing transistor ST may be connected to the first electrode of the organic light emitting diode OLED corresponding to the sensing node and the other one of the source electrode and the drain electrode of the driving transistor DR.

As described above, FIG. 3 illustrates, for example, the sub-pixel having a 3T (Transistor) 1C (Capacitor) structure including the switching transistor SW, the driving transistor DR, the capacitor Cst, the organic light emitting diode OLED, and the sensing transistor ST. However, when the compensation circuit CC is added to the sub-pixel, the sub-pixel may have various structures, such as 3T2C, 4T2C, 5TIC, and 6T2C.

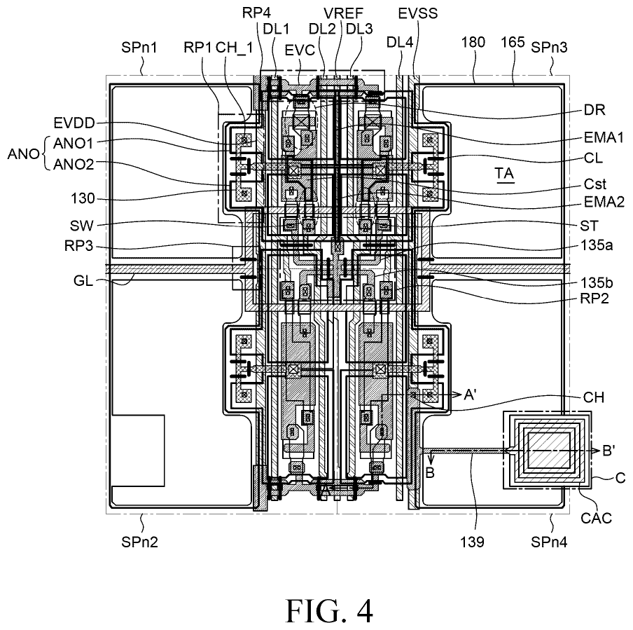

FIG. 4 is a plan view of a display device according to First Example of the present disclosure.

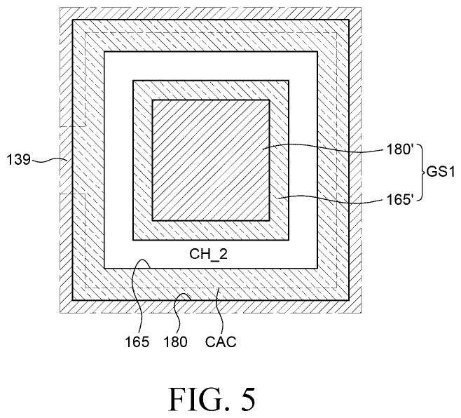

FIG. 5 is an enlarged view of an area C of FIG. 4.

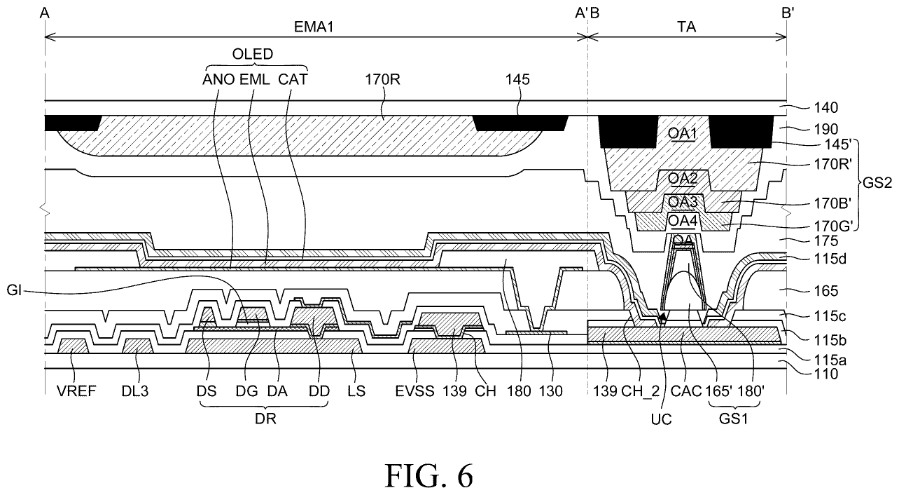

FIG. 6 is a cross-sectional view taken along a line A-A′ and a line B-B′ of FIG. 5.

FIG. 4 illustrates, for example, a transparent display device in which each of first to fourth sub-pixels SPn1 to SPn4 includes two emission areas EMA1 and EMA2 and one transmission area TA. However, the present disclosure is not limited thereto.

FIG. 5 is an enlarged view of a cathode contact part CAC, but omits the organic light emitting diode OLED and a protection layer 115d on the cathode contact part CAC for the convenience of description.

The left side of FIG. 6 shows a cross-section of a part of a first emission area EMA1 of the fourth sub-pixel SPn4. The right side of FIG. 6 shows a cross-section of a part of the transmission area TA of the fourth sub-pixel SPn4.

Referring to FIG. 4 through FIG. 6, a gate line GL may intersect first to fourth data lines DL1 to DL4 to define the first to fourth sub-pixels SPn1 to SPn4 in the display device according to First Example of the present disclosure.

Each of the first to fourth sub-pixels SPn1 to SPn4 may include two emission areas EMA1 and EMA2, i.e., the first emission area EMA1 and the second emission area EMA2, and one transmission area TA.

For example, the first to fourth sub-pixels SPn1 to SPn4 connected to the first to fourth data lines DL1 to DL4, respectively, may be commonly connected to the sensing line VREF. The sensing line VREF may be connected to the first sub-pixel SPn1 and the third sub-pixel SPn3 through a first sensing connection line 135a. Also, the sensing line VREF may be connected to the second sub-pixel SPn2 and the fourth sub-pixel SPn4 through a second sensing connection line 135b.

The first sensing connection line 135a may be connected to the second sensing connection line 135b, but the present disclosure is not limited thereto. Also, the first sensing connection line 135a and the second sensing connection line 135b may be disposed on a gate wiring layer. However, the present disclosure is not limited thereto. Herein, the gate wiring layer may be the same layer as a layer on which the gate line GL is disposed.

The power line EVDD may be disposed on one side of the first sub-pixel SPn1 and the second sub-pixel SPn2. For example, the first to fourth sub-pixels SPn1 to SPn4 may be connected to the power line EVDD through a power connection line EVC. Also, the cathode power line EVSS may be disposed on one side of the third and fourth sub-pixels SPn3 and SPn4 and connected to a second electrode CAT, which is a cathode.

In each of the first to fourth sub-pixels SPn1 to SPn4, a first anode ANO1 is disposed in the first emission area EMA1, and a second anode ANO2 is disposed in the second emission area EMA2 to form a first electrode ANO of the organic light emitting diode OLED. For example, the first anode ANO1 and the second anode ANO2 are connected to each other to form the first electrode ANO in each of the first to fourth sub-pixels SPn1 to SPn4.

The driving transistor DR, the capacitor Cst, the sensing transistor ST, and the switching transistor SW may be disposed in each of the first to fourth sub-pixels SPn1 to SPn4. The first emission area EMA1 may overlap the driving transistor DR, and the second emission area EMA2 may overlap the sensing transistor ST and the switching transistor SW.

The sensing line VREF may be connected to the sensing transistor ST of each of the first to fourth sub-pixels SPn1 to SPn4 through the first and second sensing connection lines 135a and 135b.

Also, the power line EVDD may be connected to the driving transistor DR of each of the first to fourth sub-pixels SPn1 to SPn4 through the power connection line EVC.

The gate line GL may be connected to each of the sensing and switching transistors ST and SW of the first to fourth sub-pixels SPn1 to SPn4.

Meanwhile, as described above, the cathode power line EVSS may be disposed to apply a low-potential voltage to the second electrode CAT.

The cathode power line EVSS may be electrically connected to a cathode connection line 139 through a contact hole CH. The cathode connection line 139 may extend to the transmission area TA. The cathode connection line 139 may be disposed on a source/drain wiring layer. Herein, the source/drain wiring layer may be the same layer as a layer on which a source electrode DS and a drain electrode DD are disposed. For example, a part of the cathode connection line 139 extending to the transmission area TA may form the cathode contact part CAC.

Also, the second electrode CAT may extend to the transmission area TA and may be electrically connected to an upper surface of the cathode contact part CAC exposed through a cathode contact hole CH_2. The cathode contact part CAC may be disposed on the source/drain wiring layer. The cathode contact part CAC serves to lower a resistance by applying a low-potential voltage to the second electrode CAT.

The first electrode ANO may include the first anode ANO1 and the second anode ANO2. The first anode ANO1 and the second anode ANO2 may be connected to each other through an anode connection line 130. The anode connection line 130 may extend from the drain electrode DD of the driving transistor DR and may be branched in the transmission area TA toward the first anode ANO1 and the second anode ANO2. For example, each of the first anode ANO1 and the second anode ANO2 may be electrically connected to the anode connection line 130 through an anode contact hole CH_1.

A first repair part RP1 may be disposed in an area where the first anode ANO1 and the second anode ANO2 of the first electrode ANO are connected to each other.

Also, a second repair part RP2 may be disposed in an area where the first sensing connection line 135a and the second sensing connection line 135b connected to the sensing line VREF are branched to the first to fourth sub-pixels SPn1 to SPn4.

Further, a third repair part RP3 may be disposed in each of an area where the gate line GL is branched to the first and second sub-pixels SPn and SPn2 and an area where the gate line GL is branched to the third and fourth sub-pixels SPn3 and SPn4.

Furthermore, a third repair part RP4 may be disposed at upper ends of the first and third sub-pixels SPn1 and SPn3 or lower ends of the second and fourth sub-pixels SPn2 and SPn4 where the power connection line EVC is connected to the power line EVDD.

Meanwhile, the display device may be implemented in a top emission method or a bottom emission method. For example, in the top emission method, an encapsulation substrate 140 may be bonded onto a substrate 110 on which the organic light emitting diode OLED is disposed in a state where an adhesive film 175 is disposed on the substrate 110.

It is important to maintain a uniform cell gap during a process of bonding the substrate 110 to the encapsulation substrate 140. As a distance between a dam and the adhesive film 175 increases, a lot of pressing dark spots occur due to sagging of the substrate 110 and bending of the protection layer 115d. That is, if there is no gap structure for maintaining a cell gap, a pressing dark spot may be caused by a low cell gap. Also, a pressing dark spot may be caused by foreign matter generated inside the display panel during the bonding process.

Thus, in First Example of the present disclosure, a first gap structure GS1 is provided on the cathode contact part CAC. Also, a second gap structure GS2 is provided on the encapsulation substrate 140 facing the first gap structure GS1. Thus, a uniform cell gap can be maintained during the bonding process. As a result, it is possible to suppress a pressing dark spot caused by foreign matter generated inside the display panel.

Specifically, a light shielding layer LS may be disposed on the substrate 110.

The data lines DL1 to DL4, the power line EVDD, the sensing line VREF, and the cathode power line EVSS may be disposed on the same layer as the light shielding layer LS.

A buffer layer 115a may be disposed on the substrate 110 on which the light shielding layer LS, the data lines DL1 to DL4, the power line EVDD, the sensing line VREF, and the cathode power line EVSS are disposed.

A semiconductor layer DA of the driving transistor DR may be disposed on the buffer layer 115a, and a lower capacitor electrode may be disposed to be spaced apart from the semiconductor layer DA.

Semiconductor layers of the sensing transistor ST and the switching transistor SW may be disposed on the same layer as the semiconductor layer DA of the driving transistor DR. However, the present disclosure is not limited thereto.

A gate insulating film GI may be disposed on the semiconductor layer DA and the lower capacitor electrode.

A gate electrode DG of the driving transistor DR may be disposed at a position corresponding to a channel region of the semiconductor layer DA on the gate insulating film GI.

Gate electrodes of the sensing transistor ST and the switching transistor SW, and the gate line GL may be disposed on the same layer as the gate electrode DG of the driving transistor DR. Also, the source electrode DS and the drain electrode DD of the driving transistor DR may be disposed on the same layer as the gate electrode DG of the driving transistor DR. Further, the source electrodes and the drain electrodes of the sensing transistor ST and the switching transistor SW may be disposed on the same layer as the gate electrode DG of the driving transistor DR. However, the present disclosure is not limited thereto. Also, the cathode connection line 139 may be disposed on the same layer as the gate electrode DG of the driving transistor DR. The cathode connection line 139 may be electrically connected to the cathode power line EVSS through the contact hole CH. The cathode connection line 139 may extend to the transmission area TA. Further, the cathode contact part CAC may be disposed on the same layer as the gate electrode DG of the driving transistor DR. For example, a part of the cathode connection line 139 extending to the transmission area TA may form the cathode contact part CAC.

FIG. 4 illustrates, for example, one cathode contact part CAC provided in one pixel composed of the first to fourth sub-pixels SPn1 to SPn4. However, the present disclosure is not limited thereto. A plurality of cathode contact parts CAC may be provided in one pixel.

The driving transistor DR may be configured including the semiconductor layer DA, the gate electrode DG, the source electrode DS, and the drain electrode DD. Further, the lower capacitor electrode may form the capacitor Cst together with the drain electrode DD serving as an upper capacitor electrode.

An interlayer insulating film 115b may be disposed on the substrate 110 including the driving transistor DR and the capacitor Cst.

The anode connection line 130 may be disposed on the interlayer insulating film 115b.

For example, the anode connection line 130 may be configured by a single layer or a multi-layer.

Herein, the anode connection line 130 may be connected to the drain electrode DD of the driving transistor DR. Also, the anode connection line 130 may extend to the first repair part RP1 and may be branched at the first repair part RP1 toward the first anode ANO1 and the second anode ANO2.

A passivation film 115c may be disposed on the substrate 110 including the anode connection line 130.

An overcoating layer 165 may be disposed on the passivation film 115c.

The organic light emitting diode OLED may be disposed on the overcoating layer 165.

More specifically, the first electrode ANO may be disposed on the overcoating layer 165. Herein, the first electrode ANO serves as a pixel electrode, and may be connected to the drain electrode DD of the driving transistor DR through the anode connection line 130 connected to the first electrode ANO.

The first electrode ANO may include the first anode ANO1 and the second anode ANO2. The first anode ANO1 and the second anode ANO2 may be connected to each other through the anode connection line 130. Each of the first anode ANO1 and the second anode ANO2 may be electrically connected to the anode connection line 130 through, for example, the anode contact hole CH_1.

Further, a bank layer 180 may be disposed on the substrate 110 including the first electrode ANO so as to partition the first to fourth sub-pixels SPn1 to SPn4.

For example, the first gap structure GS1 composed of an overcoating layer pattern 165′ and a bank layer pattern 180′ may be provided on the cathode contact part CAC.

For example, the overcoating layer pattern 165′ and the bank layer pattern 180′ may be formed into an island shape during a process of forming the cathode contact hole CH_2 in a predetermined region of the bank layer 180, the overcoating layer 165, the passivation film 115c, and the interlayer insulating film 115b.

A part of the upper surface of the cathode contact part CAC may be exposed through the cathode contact hole CH_2. FIG. 5 illustrates, for example, the upper surface of the cathode contact part CAC exposed through the cathode contact hole CH_2 and having a substantially quadrangular frame shape. However, the present disclosure is not limited thereto.

For example, the overcoating layer pattern 165′ may have an island shape spaced apart from the overcoating layer 165. Also, the bank layer pattern 180′ may have an island shape spaced apart from the bank layer 180. FIG. 5 illustrates, for example, the overcoating layer pattern 165′ and the bank layer pattern 180′ patterned into a substantially quadrangular shape. However, the present disclosure is not limited thereto.

An undercut UC may be provided under the first gap structure GS1 patterned into an island shape as described above. For example, the undercut UC may be formed by etching side surfaces of the interlayer insulating film 115b and the passivation film 115c under the first gap structure GS1, i.e., under the overcoating layer pattern 165′, to be further inward than the overcoating layer pattern 165′.

An organic layer EML in contact with the first electrode ANO may be disposed on the entire surface of the substrate 110. Herein, the organic layer EML includes an emission layer in which electrons and holes are recombined to emit light. The organic layer EML may also include a hole injection layer or a hole transport layer between the emission layer and the first electrode ANO. The organic layer EML may further include an electron transport layer or an electron injection layer on the emission layer.

The second electrode CAT may be disposed on the organic layer EML. The second electrode CAT serves as a cathode, and may be disposed on the entire surface of a display part and made of magnesium (Mg), calcium (Ca), aluminum (Al), silver (Ag), which have a low work function, or an alloy thereof. The second electrode CAT may be a transmission electrode and may be formed thin enough to transmit light.

Meanwhile, the organic layer EML and the second electrode CAT may extend to the transmission area TA. The organic layer EML and the second electrode CAT may be separated from each other by the undercut UC with the first gap structure GS1 interposed therebetween on the cathode contact part CAC. Herein, for example, the second electrode CAT may extend to the transmission area TA and may be electrically connected to the upper surface of the cathode contact part CAC exposed through the cathode contact hole CH_2. For example, the organic layer EML and the second electrode CAT separated by the undercut UC may be deposited on the first gap structure GS1.

The protection layer 115d may be disposed on the second electrode CAT.

Although not illustrated in the drawings, a capping layer may also be disposed on the organic light emitting diode OLED. The capping layer may be made of a material having high refractive index and light absorbance to reduce diffused reflection of external light.

The protection layer 115d may be an inorganic layer. In this case, the protection layer 115d may be made of silicon oxide (SiOx) or silicon nitride (SiNx), or may be configured by a multi-layer thereof.

The protection layer 115d may extend to the transmission area TA. For example, the protection layer 115d may extend to the transmission area TA, and may also be disposed on the second electrode CAT on the first gap structure GS1.

The adhesive film 175 and the encapsulation substrate 140 may be disposed on the protection layer 115d.

For example, in the top emission method, the encapsulation substrate 140 may be bonded onto the substrate 110 on which the organic light emitting diode OLED is disposed in a state where the adhesive film 175 is disposed on the substrate 110.

A black matrix 145 may be disposed on a surface of the encapsulation substrate 140 facing the substrate 110. Herein, the surface of the encapsulation substrate 140 facing the substrate 110 will be referred to as “upper surface” for the convenience of description.

For example, the black matrix 145 may be spaced apart from the black matrix 145 disposed in another adjacent sub-pixel and thus may include an opening.

A color filter may be disposed on the opening. For example, the color filter may be disposed to overlap a part of an upper surface of the black matrix 145. For example, the color filter may include a red color filter layer 170R, a green color filter layer, and a blue color filter layer.

An insulating layer 190 may be disposed on the encapsulation substrate 140 including the color filter. Herein, the insulating layer 190 may be an overcoating layer or a planarization layer. The insulating layer 190 may serve to planarize the encapsulation substrate 140.

The second gap structure GS2 in which the color filter and the black matrix are deposited may be disposed on the encapsulation substrate 140 facing the first gap structure GS1.

For example, the second gap structure GS2 may be composed of a black matrix pattern 145′, a red color filter layer pattern 170R′, a blue color filter layer pattern 170B′, and a green color filter layer pattern 170G′ on the encapsulation substrate 140. However, the present disclosure is not limited thereto.

For example, the black matrix pattern 145′ including a first concave region OA1 facing the first gap structure GS1 may be disposed on the encapsulation substrate 140.

For example, the first concave region OA1 may correspond in shape to an upper surface of the first gap structure GS1. For example, the first concave region OA1 may have a greater size, i.e., a greater area, than the upper surface of the first gap structure GS1.

For example, the black matrix pattern 145′ may have a circular or quadrangular frame shape excluding the first concave region OA1, but is not limited thereto.

For example, the black matrix pattern 145′ may have the same or smaller width than the cathode contact part CAC, but is not limited thereto.

For example, the black matrix pattern 145′ may have a greater width than the first gap structure GS1 and the second gap structure GS2, but is not limited thereto.

For example, the black matrix pattern 145′ may be prepared in the same process as the black matrix 145 and formed to have a greater thickness than the black matrix 145, but is not limited thereto. For example, the black matrix pattern 145′ may have a thickness of 3 μm or more. For example, the black matrix pattern 145′ may have a positive taper at an angle of 70 degrees or more, but is not limited thereto. The black matrix pattern 145′ may have a reverse taper.

The black matrix pattern 145′ may be introduced to suppress a change in bonding state between the substrate 110 and the encapsulation substrate 140 caused by a change in pressure. That is, when the substrate 110 is bonded to the encapsulation substrate 140, the dam and the adhesive film 175 are coated in a vacuum state and then, the dam is cured, followed by thermal curing of the adhesive film 175 at atmospheric pressure. Herein, a filling material of the adhesive film 175 may flow in an uncured state with viscosity. Therefore, a change in bonding state, such as a micro distortion, between the substrate 110 and the encapsulation substrate 140 may be caused by a change in pressure. Since the first concave region OA1 is formed in the black matrix pattern 145′, it is possible to suppress a movement of the second gap structure GS2.

For example, the red color filter layer pattern 170R′ may be disposed on the black matrix pattern 145′ including the first concave region OA1.

For example, the red color filter layer pattern 170R′ may be disposed on the black matrix pattern 145′ so as to fill in the first concave region OA1, but is not limited thereto. For example, the red color filter layer pattern 170R′ may be prepared in the same process as the red color filter layer 170R and formed to have substantially the same thickness as the red color filter layer 170R. However, the present disclosure is not limited thereto.

For example, a central portion of the red color filter layer pattern 170R′ corresponding to the first concave region OA1 may be dented to form a second concave region OA2 having a smaller size, e.g., a smaller area, than the first concave region OA1.

For example, the blue color filter layer pattern 170B′ may be disposed on the red color filter layer pattern 170R′ including the second concave region OA2.

For example, the blue color filter layer pattern 170B′ may be disposed on the red color filter layer pattern 170R′ so as to fill in the second concave region OA2, but is not limited thereto. For example, the blue color filter layer pattern 170B′ may be prepared in the same process as the blue color filter layer and formed to have substantially the same thickness as the blue color filter layer. However, the present disclosure is not limited thereto.

For example, a central portion of the blue color filter layer pattern 170B′ corresponding to the second concave region OA2 may be dented to form a third concave region OA3 having a smaller size, e.g., a smaller area, than the second concave region OA2.

For example, the green color filter layer pattern 170G′ may be disposed on the blue color filter layer pattern 170B′ including the third concave region OA3.

For example, the green color filter layer pattern 170G′ may be disposed on the blue color filter layer pattern 170B′ so as to fill in the third concave region OA3, but is not limited thereto. For example, the green color filter layer pattern 170G′ may be prepared in the same process as the green color filter layer and formed to have substantially the same thickness as the green color filter layer. However, the present disclosure is not limited thereto.

For example, a central portion of the green color filter layer pattern 170G′ corresponding to the third concave region OA3 may be dented to form a fourth concave region OA4 having a smaller size, e.g., a smaller area, than the third concave region OA3.

For example, the first concave region OA1, the second concave region OA2, the third concave region OA3, and the fourth concave region OA4 may correspond in shape to the upper surface of the first gap structure GS1. For example, the fourth concave region OA4 may have a greater size, i.e., a greater area, than the upper surface of the first gap structure GS1.

There has been described an example where the red color filter layer pattern 170R′, the blue color filter layer pattern 170B′, and the green color filter layer pattern 170G′ are sequentially deposited on the black matrix pattern 145′ to form the second gap structure GS2. However, the present disclosure is not limited to the sequence of laminating the color filter layer patterns. If the black matrix pattern 145′ has a relatively large thickness and has a high taper angle, the sequence of laminating the color filter layer patterns is not an issue.

For example, the insulating layer 190 may be disposed on the encapsulation substrate 140 including the green color filter layer pattern 170G′.

For example, a central portion of the insulating layer 190 corresponding to the fourth concave region OA4 may be dented to form a concave region OA having a smaller size, e.g., a smaller area, than the fourth concave region OA4.

For example, when the first gap structure GS1 has a width of 15 μm, the concave region OA of the insulating layer 190 may have a width of at least 20 μm. Also, when the first gap structure GS1 has a taper angle of 70 degrees, the first concave region OA1 of the black matrix pattern 145′ may have a width of at least 27 μm. The width of the first concave region OA1 may vary depending on the thickness and the taper angle of the black matrix pattern 145′. For example, as the taper angle of the black matrix pattern 145′ increases, the width of the first concave region OA1 may decrease.

Even if a predetermined cell gap cannot be implemented by controlling the thicknesses of the second gap structure GS2 and the insulating layer 190, it can be compensated for by controlling the thickness of the overcoating layer pattern 165′. Alternatively, it can be compensated for by providing an additional spacer on the first gap structure GS1.

For example, an upper end of the first gap structure GS1 may be inserted into the concave region OA.

As described above, in First Example of the present disclosure, the first gap structure GS1 is provided on the cathode contact part CAC. Also, the second gap structure GS2 including the concave region OA is provided on the encapsulation substrate 140 facing the first gap structure GS1. Thus, a uniform cell gap can be maintained during a bonding process by suppressing a movement of the first gap structure GS1. Therefore, it is possible to suppress a pressing dark spot caused by foreign matter generated inside the display device.

Further, the undercut UC is provided under the first gap structure GS1. Thus, even when a crack occurs in the protection layer 115d on the first gap structure GS1 due to a pressure applied during the bonding process, the undercut UC can suppress the propagation of the crack to the neighboring sub-pixels SPn1 to SPn4. Therefore, it is possible to improve reliability.

In particular, the first gap structure GS1 of the present disclosure is disposed on the cathode contact part CAC of the transmission area TA in which almost no circuit components are disposed. Thus, the effect of the crack on protection layer 115d can be minimized, which is in favor of reliability. Thus, the cathode contact part CAC may be disposed in the transmission area TA at a boundary between the sub-pixels SPn1 to SPn.

Although not illustrated in the drawings, substantially the same structure as the second gap structure GS2 may also be provided on the second repair part RP2. Thus, it is possible to maintain a uniform cell gap between the substrate 110 and the encapsulation substrate 140. In addition to the light shielding layer LS and the gate wiring layer, the inorganic insulating films, such as the interlayer insulating film 115b and the passivation film 115c, are deposited on the second repair part RP2. Therefore, the second repair part RP2 has a greater height than other parts, which facilitates disposition of a gap structure. Further, for example, an additional spacer may be provided on the substrate 110 of the second repair part RP2 in consideration of a cell gap with respect to the cathode contact part CAC. That is, for example, an additional spacer may be provided on the substrate 110 of the second repair part RP2 to form a uniform cell gap between the cathode contact part CAC and the second repair part RP2.

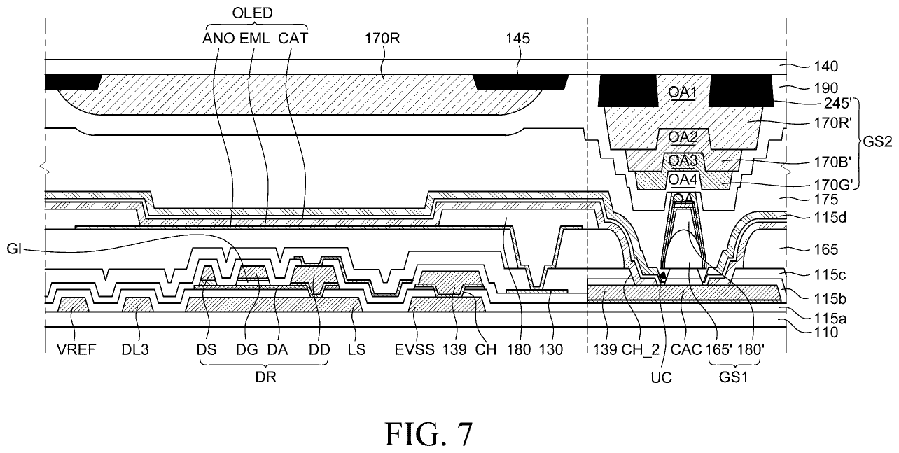

FIG. 7 is a cross-sectional view of a display device according to Second Example of the present disclosure.

The display device according to Second Example of the present disclosure as shown in FIG. 7 is substantially the same as the display device according to First Example of the present disclosure as shown in FIG. 4 through FIG. 6 except a configuration of the second gap structure GS2. The same components are denoted by the same reference numerals and the description thereof may be omitted.

FIG. 7 shows a cross-section of substantially the same part as FIG. 6. The left side of FIG. 7 shows a cross-section of a part of the first emission area EMA1 of the fourth sub-pixel SPn4. The right side of FIG. 7 shows a cross-section of a part of the transmission area TA of the fourth sub-pixel SPn4.

Referring to FIG. 7, in the display device according to Second Example of the present disclosure, the encapsulation substrate 140 may be bonded onto the substrate 110 on which the organic light emitting diode OLED is disposed in a state where the adhesive film 175 is disposed on the substrate 110.

Herein, in Second Example of the present disclosure as in First Example of the present disclosure described above, the first gap structure GS1 is provided on the cathode contact part CAC. Also, the second gap structure GS2 is provided on the encapsulation substrate 140 facing the first gap structure GS1.

For example, the first gap structure GS1 composed of the overcoating layer pattern 165′ and the bank layer pattern 180′ may be provided on the cathode contact part CAC.

Further, the second gap structure GS2 in which the color filter and the black matrix are deposited may be disposed on the encapsulation substrate 140 facing the first gap structure GS1.

For example, the second gap structure GS2 according to Second Example of the present disclosure may be composed of a black matrix pattern 245′, the red color filter layer pattern 170R′, the blue color filter layer pattern 170B′, and the green color filter layer pattern 170G′ on the encapsulation substrate 140.

For example, the black matrix pattern 245′ including the first concave region OA1 facing the first gap structure GS1 may be disposed on the encapsulation substrate 140.

For example, the first concave region OA1 may correspond in shape to the upper surface of the first gap structure GS1. For example, the first concave region OA1 may have a greater size, i.e., a greater area, than the upper surface of the first gap structure GS1.

For example, the black matrix pattern 245′ may be prepared in the same process as the black matrix 145 and formed to have a greater thickness than the black matrix 145, but is not limited thereto. For example, the black matrix pattern 245′ may have a thickness of 3 μm or more. For example, the black matrix pattern 245′ may have a reverse taper.

For example, the red color filter layer pattern 170R′ including the second concave region OA2, the blue color filter layer pattern 170B′ including the third concave region OA3, and the green color filter layer pattern 170G′ the fourth concave region OA4 may be sequentially deposited on the black matrix pattern 245′ including the first concave region OA1.

For example, the first concave region OA1, the second concave region OA2, the third concave region OA3, and the fourth concave region OA4 may correspond in shape to the upper surface of the first gap structure GS1. For example, the fourth concave region OA4 may have a greater size, i.e., a greater area, than the upper surface of the first gap structure GS1.

As described above, the present disclosure is not limited to the sequence of laminating the color filter layer patterns. If the black matrix pattern 245′ has a relatively large thickness and has a high taper angle, the sequence of laminating the color filter layer patterns is not an issue.

For example, the insulating layer 190 including the concave region OA may be disposed on the encapsulation substrate 140 including the green color filter layer pattern 170G′.

Even if a predetermined cell gap cannot be implemented by controlling the thicknesses of the second gap structure GS2 and the insulating layer 190, it can be compensated for by controlling the thickness of the overcoating layer pattern 165′. Alternatively, it can be compensated for by providing an additional spacer on the first gap structure GS1.

For example, the upper end of the first gap structure GS1 may be inserted into the concave region OA.

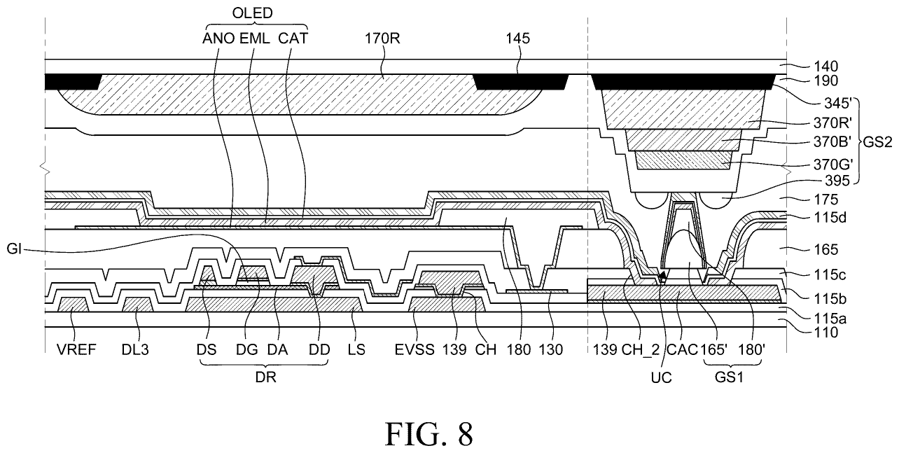

FIG. 8 is a cross-sectional view of a display device according to Third Example of the present disclosure.

The display device according to Third Example of the present disclosure as shown in FIG. 8 is substantially the same as the display device according to First Example of the present disclosure as shown in FIG. 4 through FIG. 6 except a configuration of the second gap structure GS2. The same components are denoted by the same reference numerals and the description thereof may be omitted.

FIG. 8 shows a cross-section of substantially the same part as FIG. 6. The left side of FIG. 8 shows a cross-section of a part of the first emission area EMA1 of the fourth sub-pixel SPn4. The right side of FIG. 8 shows a cross-section of a part of the transmission area TA of the fourth sub-pixel SPn4.

Referring to FIG. 8, in the display device according to Third Example of the present disclosure, the encapsulation substrate 140 may be bonded onto the substrate 110 on which the organic light emitting diode OLED is disposed in a state where the adhesive film 175 is disposed on the substrate 110.

In Third Example of the present disclosure as in First and Second Examples of the present disclosure described above, the first gap structure GS1 is provided on the cathode contact part CAC. Also, the second gap structure GS2 is provided on the encapsulation substrate 140 facing the first gap structure GS1.

For example, the first gap structure GS1 composed of the overcoating layer pattern 165′ and the bank layer pattern 180′ may be provided on the cathode contact part CAC.

Also, the second gap structure GS2 in which the color filter and the black matrix are deposited may be disposed on the encapsulation substrate 140 facing the first gap structure GS1.

For example, the second gap structure GS2 according to Third Example of the present disclosure may be composed of a black matrix pattern 345′, a red color filter layer pattern 370R′, a blue color filter layer pattern 370B′, and a green color filter layer pattern 370G′ on the encapsulation substrate 140.

For example, the black matrix pattern 345′ may be disposed on the encapsulation substrate 140.

For example, the black matrix pattern 345′ may be prepared in the same process as the black matrix 145 and formed to have the same thickness as the black matrix 145, but is not limited thereto.

For example, the red color filter layer pattern 370R′, the blue color filter layer pattern 370B′, and the green color filter layer pattern 370G′ may be sequentially deposited on the black matrix pattern 345′.

For example, the width may be decreased in sequence of the black matrix pattern 345′, the red color filter layer pattern 370R′, the blue color filter layer pattern 370B′, and the green color filter layer pattern 370G′. However, the present disclosure is not limited thereto.

As described above, the present disclosure is not limited to the sequence of laminating the color filter layer patterns.

For example, the insulating layer 190 may be disposed on the encapsulation substrate 140 including a green color filter layer pattern 470G′.

Even if a predetermined cell gap cannot be implemented by controlling the thicknesses of the second gap structure GS2 and the insulating layer 190, it can be compensated for by controlling the thickness of the overcoating layer pattern 165′. Alternatively, it can be compensated for by providing an additional spacer on the first gap structure GS1.

For example, the first gap structure GS1 may be in contact with the insulating layer 190. Specifically, the protection layer 115d on the first gap structure GS1 may be in contact with the insulating layer 190.

Meanwhile, according to Third Example of the present disclosure, a spacer 395 may be disposed on an upper edge of the insulating layer 190 so as to suppress a movement of the first gap structure GS1.

The spacer 395 may be introduced to suppress a change in bonding state between the substrate 110 and the encapsulation substrate 140 caused by a change in pressure. As described above, when the substrate 110 is bonded to the encapsulation substrate 140, the dam and the adhesive film 175 are coated in a vacuum state and then, the dam is cured, followed by thermal curing of the adhesive film 175 at atmospheric pressure. Herein, a filling material of the adhesive film 175 may flow in an uncured state with viscosity. Therefore, a change in bonding state, such as a micro distortion, between the substrate 110 and the encapsulation substrate 140 may be caused by a change in pressure. Since the spacer 395 is further provided on the upper edge of the insulating layer 190, it is possible to suppress a change in bonding state between the substrate 110 and the encapsulation substrate 140.

The spacer 395 may have a circular or quadrangular frame shape enclosing the upper end of the first gap structure GS1, but is not limited thereto. For example, the spacer 395 may be configured as a single body, or may be divided into a plurality of bodies.

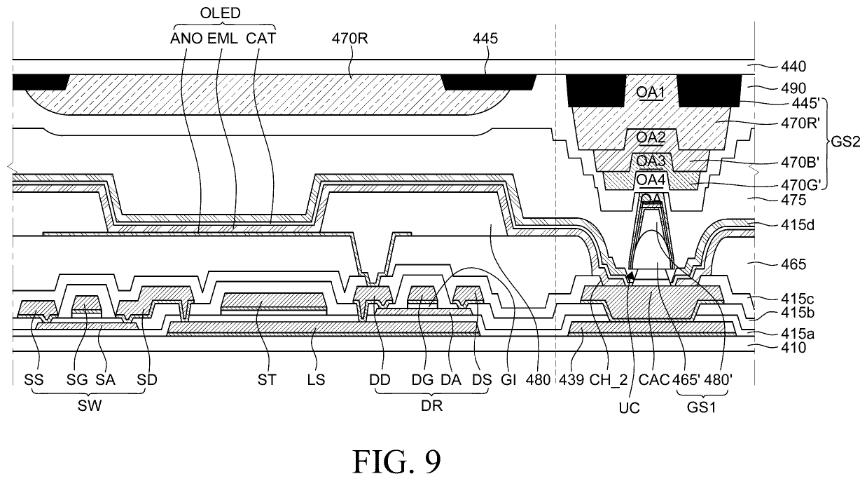

FIG. 9 is a cross-sectional view of a display device according to Fourth Example of the present disclosure.

FIG. 9 illustrates, for example, a typical top emission display device in which one sub-pixel includes one emission area. However, the present disclosure is not limited thereto.

The left side of FIG. 9 shows a cross-section of a part of an emission area of one sub-pixel. The right side of FIG. 9 shows a cross-section of a part of the cathode contact part CAC connected to a cathode connection line 439.

Referring to FIG. 9, the light shielding layer LS may be disposed on a substrate 410.

A data line, a power line, a sensing line, and a cathode power line may be disposed on the same layer as the light shielding layer LS. Also, the cathode connection line 439 may be disposed on the same layer as the light shielding layer LS.

A buffer layer 415a may be disposed on the substrate 410 on which the light shielding layer LS, the data line, the power line, the sensing line, and the cathode power line are disposed.

For example, a part of the light shielding layer LS may form the lower capacitor electrode. However, the present disclosure is not limited thereto.

The semiconductor layer DA of the driving transistor DR may be disposed on the buffer layer 415a.

The sensing transistor and a semiconductor layer SA of the switching transistor SW may be disposed on the same layer as the semiconductor layer DA of the driving transistor DR. However, the present disclosure is not limited thereto.

The gate insulating film GI may be disposed on each of the semiconductor layers DA and SA.

The gate electrode DG of the driving transistor DR may be disposed at the position corresponding to the channel region of the semiconductor layer DA on the gate insulating film GI.

The sensing transistor and a gate electrode SG and a gate line of the switching transistor SW may be disposed on the same layer as the gate electrode DG of the driving transistor DR. Also, an upper capacitor electrode ST may be disposed on the same layer as the gate electrode DG of the driving transistor DR. Herein, the upper capacitor electrode ST may form a capacitor together with the light shielding layer LS serving as a lower capacitor electrode.

For example, an interlayer insulating film 415b may be disposed on the substrate 410 including the driving transistor DR, the capacitor, the sensing transistor, and the switching transistor SW.

The source electrode DS and the drain electrode DD of the driving transistor DR may be disposed on the interlayer insulating film 415b. Also, the sensing transistor and a source electrode SS and a drain electrode SD of the switching transistor SW may be disposed on the same layer as the source electrode DS and the drain electrode DD of the driving transistor DR. However, the present disclosure is not limited thereto. Further, the cathode contact part CAC may be disposed on the same layer as the source electrode DS and the drain electrode DD of the driving transistor DR. Herein, for example, the cathode contact part CAC may be disposed on the cathode connection line 439 so as to partially overlap the cathode connection line 439. Furthermore, for example, the cathode connection line 439 may be connected to the cathode contact part CAC through a contact hole.

For example, a passivation film 415c may be disposed on the substrate 410 including the source electrode DS and the drain electrode DD of the driving transistor DR.

An overcoating layer 465 may be disposed on the passivation film 415c.

The organic light emitting diode OLED may be disposed on the overcoating layer 465.

More specifically, the first electrode ANO may be disposed on the overcoating layer 465. Herein, the first electrode ANO serves as a pixel electrode, and may be connected to the drain electrode DD of the driving transistor DR through a contact hole.

Further, a bank layer 480 may be disposed on the substrate 410 including the first electrode ANO so as to partition sub-pixels.

For example, the first gap structure GS1 composed of an overcoating layer pattern 465′ and a bank layer pattern 480′ may be provided on the cathode contact part CAC.

For example, the overcoating layer pattern 465′ and the bank layer pattern 480′ may be formed into an island shape during the process of forming the cathode contact hole CH_2 in a predetermined region of the bank layer 480, the overcoating layer 465, the passivation film 415c, and the interlayer insulating film 415b.

A part of the upper surface of the cathode contact part CAC may be exposed through the cathode contact hole CH_2.

For example, the overcoating layer pattern 465′ may have an island shape spaced apart from the overcoating layer 465. Also, the bank layer pattern 480′ may have an island shape spaced apart from the bank layer 480.

The undercut UC may be provided under the first gap structure GS1 patterned into an island shape as described above. For example, the undercut UC may be formed by etching side surfaces of the interlayer insulating film 415b and the passivation film 415c under the first gap structure GS1, i.e., under the overcoating layer pattern 465′, to be further inward than the overcoating layer pattern 465′.

The organic layer EML in contact with the first electrode ANO may be disposed on the entire surface of the substrate 410. Herein, the organic layer EML includes an emission layer in which electrons and holes are recombined to emit light. The organic layer EML may also include a hole injection layer or a hole transport layer between the emission layer and the first electrode ANO. The organic layer EML may further include an electron transport layer or an electron injection layer on the emission layer.

The second electrode CAT may be disposed on the organic layer EML.

For example, the organic layer EML and the second electrode CAT may extend toward the cathode connection line 439. The organic layer EML and the second electrode CAT may be separated from each other by the undercut UC with the first gap structure GS1 interposed therebetween on the cathode contact part CAC. For example, the second electrode CAT may be electrically connected to the upper surface of the cathode contact part CAC exposed through the cathode contact hole CH_2. For example, the organic layer EML and the second electrode CAT separated by the undercut UC may be deposited on the first gap structure GS1.

A protection layer 415d may be disposed on the second electrode CAT.

The protection layer 415d may extend toward the cathode connection line 439. For example, the protection layer 415d may be disposed on the second electrode CAT on the first gap structure GS1.

An adhesive film 475 and an encapsulation substrate 440 may be disposed on the protection layer 415d.

For example, in the top emission method, the encapsulation substrate 440 may be bonded onto the substrate 410 on which the organic light emitting diode OLED is disposed in a state where the adhesive film 475 is disposed on the substrate 410.

A black matrix 445 may be disposed on a surface of the encapsulation substrate 440 facing the substrate 410. Herein, the surface of the encapsulation substrate 440 facing the substrate 410 will be referred to as “upper surface” for the convenience of description.

For example, the black matrix 445 may be spaced apart from the black matrix 445 disposed in another adjacent sub-pixel and thus may include an opening.

A color filter may be disposed on the opening. For example, the color filter may be disposed to overlap a part of an upper surface of the black matrix 445. For example, the color filter may include a red color filter layer 470R, a green color filter layer, and a blue color filter layer.

An insulating layer 490 may be disposed on the encapsulation substrate 440 including the color filter. Herein, the insulating layer 490 may be an overcoating layer or a planarization layer. The insulating layer 490 may serve to planarize the encapsulation substrate 440.

The second gap structure GS2 in which the color filter and the black matrix are deposited may be disposed on the encapsulation substrate 440 facing the first gap structure GS1.

For example, the second gap structure GS2 may be composed of a black matrix pattern 445′, a red color filter layer pattern 470R′, a blue color filter layer pattern 470B′, and a green color filter layer pattern 470G′ on the encapsulation substrate 440. However, the present disclosure is not limited thereto.

For example, the black matrix pattern 445′ including the first concave region OA1 facing the first gap structure GS1 may be disposed on the encapsulation substrate 440.

For example, the black matrix pattern 445′ may be prepared in the same process as the black matrix 445 and formed to have a greater thickness than the black matrix 445, but is not limited thereto. For example, the black matrix pattern 445′ may have a positive taper at an angle of 70 degrees or more, but is not limited thereto. The black matrix pattern 445′ may have a reverse taper.

For example, the red color filter layer pattern 470R′ including the second concave region OA2 may be disposed on the black matrix pattern 445′ including the first concave region OA1.

For example, the red color filter layer pattern 470R′ may be disposed on the black matrix pattern 445′ so as to fill in the first concave region OA1, but is not limited thereto.

For example, the blue color filter layer pattern 470B′ including the third concave region OA3 may be disposed on the red color filter layer pattern 470R′ including the second concave region OA2.

For example, the blue color filter layer pattern 470B′ may be disposed on the red color filter layer pattern 470R′ so as to fill in the second concave region OA2, but is not limited thereto.

For example, the green color filter layer pattern 470G′ including the fourth concave region OA4 may be disposed on the blue color filter layer pattern 470B′ including the third concave region OA3.

For example, the green color filter layer pattern 470G′ may be disposed on the blue color filter layer pattern 470B′ so as to fill in the third concave region OA3, but is not limited thereto.

There has been described an example where the red color filter layer pattern 470R′, the blue color filter layer pattern 470B′, and the green color filter layer pattern 470G′ are sequentially deposited on the black matrix pattern 445′ to form the second gap structure GS2. However, the present disclosure is not limited to the sequence of laminating the color filter layer patterns.

For example, the insulating layer 490 including the concave region OA may be disposed on the encapsulation substrate 440 including the green color filter layer pattern 470G′.

Even if a predetermined cell gap cannot be implemented by controlling the thicknesses of the second gap structure GS2 and the insulating layer 490, it can be compensated for by controlling the thickness of the overcoating layer pattern 465′. Alternatively, it can be compensated for by providing an additional spacer on the first gap structure GS1.

For example, the upper end of the first gap structure GS1 may be inserted into the concave region OA.

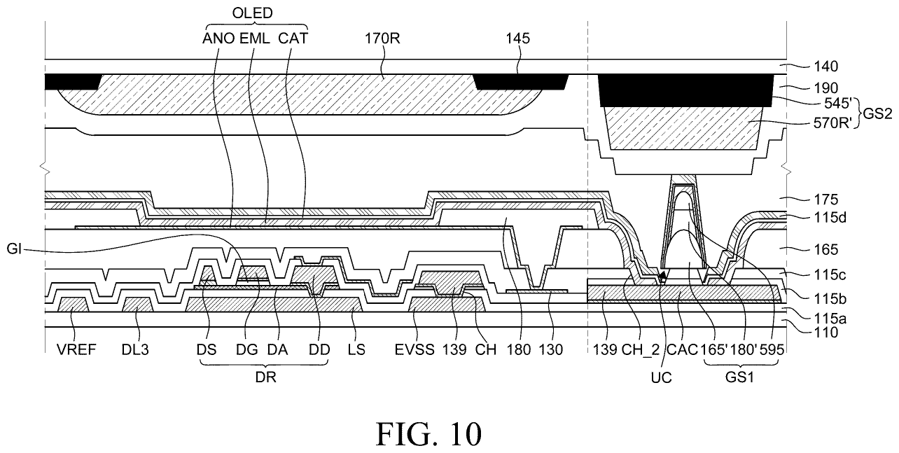

FIG. 10 is a cross-sectional view of a display device according to Fifth Example of the present disclosure.

The display device according to Fifth Example of the present disclosure as shown in FIG. 10 is substantially the same as the display device according to First Example of the present disclosure as shown in FIG. 4 through FIG. 6 except a configuration of the first gap structure GS1 and the second gap structure GS2. The same components are denoted by the same reference numerals and the description thereof may be omitted.

FIG. 10 shows a cross-section of substantially the same part as FIG. 6. The left side of FIG. 10 shows a cross-section of a part of the first emission area EMA1 of the fourth sub-pixel SPn4. The right side of FIG. 10 shows a cross-section of a part of the transmission area TA of the fourth sub-pixel SPn4.

Referring to FIG. 10, in the display device according to Fifth Example of the present disclosure, the encapsulation substrate 140 may be bonded onto the substrate 110 on which the organic light emitting diode OLED is disposed in a state where the adhesive film 175 is disposed on the substrate 110.

Herein, in Fifth Example of the present disclosure as in First Example of the present disclosure described above, the first gap structure GS1 is provided on the cathode contact part CAC. Also, the second gap structure GS2 is provided on the encapsulation substrate 140 facing the first gap structure GS1.

For example, the first gap structure GS1 composed of the overcoating layer pattern 165′, the bank layer pattern 180′, and a spacer 595 may be provided on the cathode contact part CAC.

For example, the spacer 595 may be made of the same transparent organic material as a spacer on the bank layer 180. For example, the spacer 595 may be made of one of polyimide, photo acryl, and benzocyclobutene (BCB), which are transparent organic materials.

For example, the first gap structure GS1 may have a width gradually decreases upwards. That is, for example, the overcoating layer pattern 165′ may have a greater width than the bank layer pattern 180′ and the spacer 595, and the bank layer pattern 180′ may have a greater width than the spacer 595.

Further, the second gap structure GS2 in which the color filter and the black matrix are deposited may be disposed on the encapsulation substrate 140 facing the first gap structure GS1.

For example, the second gap structure GS2 according to Fifth Example of the present disclosure may be composed of a black matrix pattern 545′ and a red color filter layer pattern 570R′ on the encapsulation substrate 140. However, the present disclosure is not limited thereto. A blue color filter layer pattern or a green color filter layer pattern may be used instead of the red color filter layer pattern 570R′. The blue color filter layer pattern or the green color filter layer pattern may be further deposited in addition to the red color filter layer pattern 570R′. The components to be included in the second gap structure GS2 may be determined by the height of the spacer 595 of the first gap structure GS1.

For example, the black matrix pattern 545′ may be disposed on the encapsulation substrate 140 so as to face the first gap structure GS1.

For example, the black matrix pattern 545′ may be prepared in the same process as the black matrix 145 and formed to have a greater thickness than the black matrix 145, but is not limited thereto.

For example, the red color filter layer pattern 570R′ may be deposited on the black matrix pattern 545′.

For example, an upper surface of the red color filter layer pattern 570R′ may have a greater size, i.e., a greater area, than the upper surface of the first gap structure GS1.

For example, the insulating layer 190 may be disposed on the encapsulation substrate 140 including the red color filter layer pattern 570R′. Also, the insulating layer 190 may be in contact with the upper surface of the first gap structure GS1.

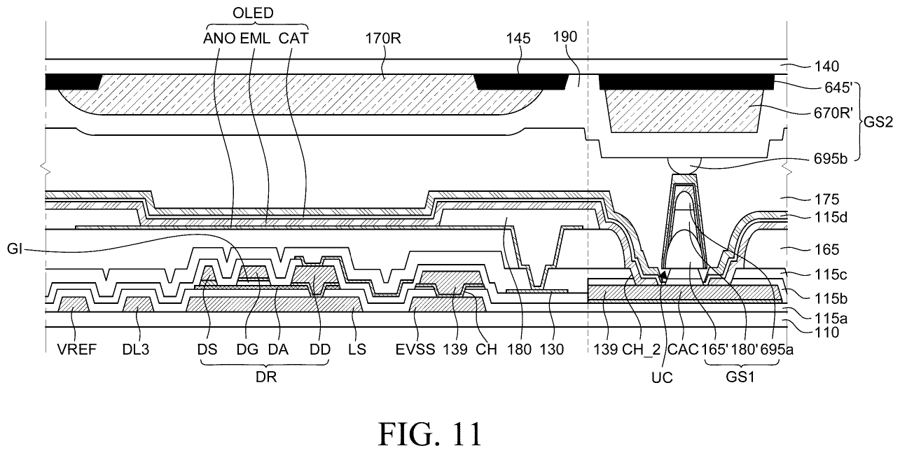

FIG. 11 is a cross-sectional view of a display device according to Sixth Example of the present disclosure.

The display device according to Sixth Example of the present disclosure as shown in FIG. 11 is substantially the same as the display device according to First Example of the present disclosure as shown in FIG. 4 through FIG. 6 except a configuration of the first gap structure GS1 and the second gap structure GS2. The same components are denoted by the same reference numerals and the description thereof may be omitted.

FIG. 11 shows a cross-section of substantially the same part as FIG. 6. The left side of FIG. 11 shows a cross-section of a part of the first emission area EMA1 of the fourth sub-pixel SPn4. The right side of FIG. 11 shows a cross-section of a part of the transmission area TA of the fourth sub-pixel SPn4.

Referring to FIG. 11, in the display device according to Sixth Example of the present disclosure, the encapsulation substrate 140 may be bonded onto the substrate 110 on which the organic light emitting diode OLED is disposed in a state where the adhesive film 175 is disposed on the substrate 110.

Herein, in Sixth Example of the present disclosure as in First Example of the present disclosure described above, the first gap structure GS1 is provided on the cathode contact part CAC. Also, the second gap structure GS2 is provided on the encapsulation substrate 140 facing the first gap structure GS1.

For example, the first gap structure GS1 composed of the overcoating layer pattern 165′, the bank layer pattern 180′, and a first spacer 695a may be provided on the cathode contact part CAC.

For example, the first spacer 695a may be made of the same transparent organic material as the spacer on the bank layer 180. For example, the first spacer 695a may be made of one of polyimide, photo acryl, and benzocyclobutene (BCB), which are transparent organic materials.

Further, the second gap structure GS2 in which the color filter and the black matrix are deposited may be disposed on the encapsulation substrate 140 facing the first gap structure GS1.

For example, the second gap structure GS2 according to Sixth Example of the present disclosure may be composed of a black matrix pattern 645′ and a red color filter layer pattern 670R′ on the encapsulation substrate 140. However, the present disclosure is not limited thereto. A blue color filter layer pattern or a green color filter layer pattern may be used instead of the red color filter layer pattern 670R′. The blue color filter layer pattern or the green color filter layer pattern may be further deposited in addition to the red color filter layer pattern 670R′. The components to be included in the second gap structure GS2 may be determined by the height of the first spacer 695a of the first gap structure GS1.

For example, the black matrix pattern 645′ may be disposed on the encapsulation substrate 140 so as to face the first gap structure GS1.

For example, the black matrix pattern 645′ may be prepared in the same process as the black matrix 145 and formed to have the same thickness as the black matrix 145, but is not limited thereto.

For example, the red color filter layer pattern 670R′ may be deposited on the black matrix pattern 645′.

For example, an upper surface of the red color filter layer pattern 670R′ may have a greater size, i.e., a greater area, than the upper surface of the first gap structure GS1.

For example, the insulating layer 190 may be disposed on the encapsulation substrate 140 including the red color filter layer pattern 670R′. For example, a second spacer 695b may be disposed on the insulating layer 190 facing the first gap structure GS1. The second spacer 695b may be in contact with the upper surface of the first gap structure GS1. For example, the second spacer 695b may be made of one of polyimide, photo acryl, and benzocyclobutene (BCB).

As described above, in Sixth Example of the present disclosure unlike Fifth Example, the black matrix pattern 645′ has the same thickness as the black matrix 145. Thus, a predetermined cell gap can be implemented by further providing the second spacer 695b on the insulating layer 190.

In First to Sixth Examples described above, the undercut UC is provided under the first gap structure GS1 patterned into an island shape. Thus, even when a crack occurs in the protection layer 115d on the first gap structure GS1 during a bonding process, the undercut UC can suppress the propagation of the crack to the neighboring sub-pixels SPn1 to SPn4. Therefore, it is possible to improve reliability. That is, each of First to Sixth Examples has a stronger structure against a crack occurring in the protection layer 115d.

However, the present disclosure is not limited to the above-described structure. A pair of first gap structures may be provided on both sides of a cathode contact part. Also, a second gap structure in which a color filter and a black matrix are deposited as described above may be provided on the pair of first gap structures. Details thereof will be described below with reference to the accompanying drawings.

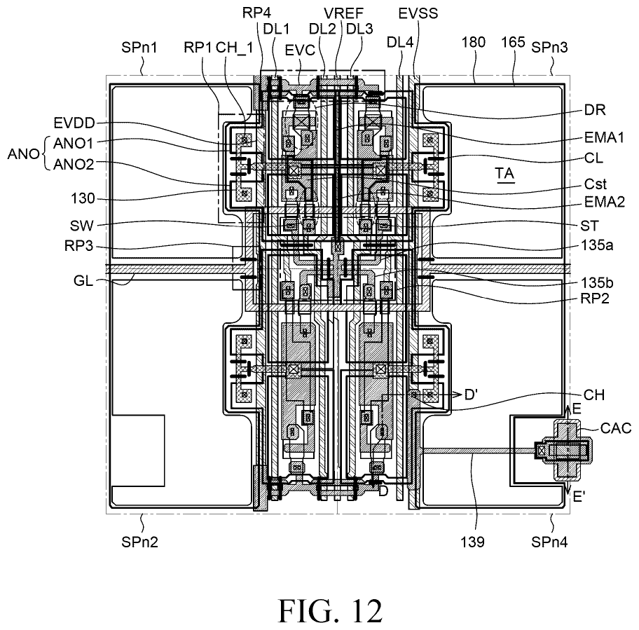

FIG. 12 is a plan view of a display device according to Seventh Example of the present disclosure.

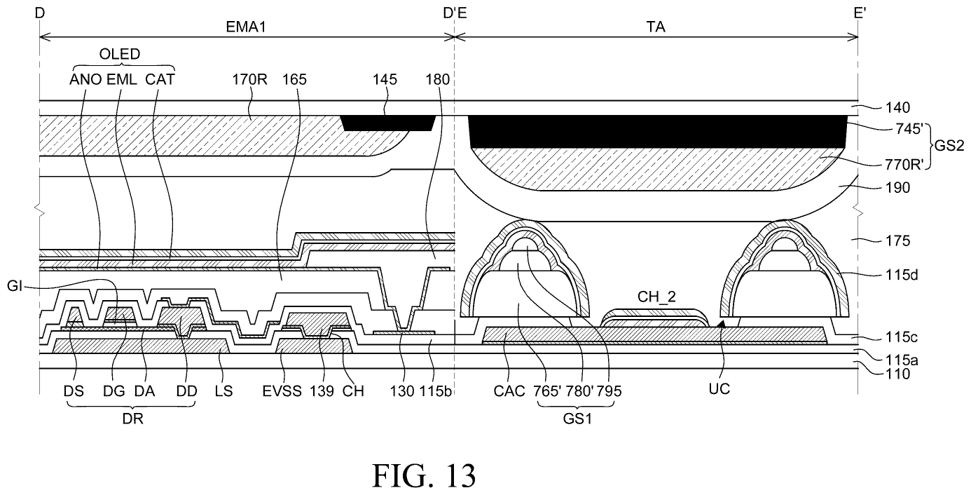

FIG. 13 is a cross-sectional view taken along a line D-D′ and a line E-E′ of FIG. 12.

FIG. 12 illustrates, for example, a transparent display device in which each of the first to fourth sub-pixels SPn1 to SPn4 includes two emission areas EMA1 and EMA2 and one transmission area TA. However, the present disclosure is not limited thereto.

The left side of FIG. 13 shows a cross-section of a part of the first emission area EMA1 of the fourth sub-pixel SPn4. The right side of FIG. 13 shows a cross-section of a part of the transmission area TA of the fourth sub-pixel SPn4.

The display device according to Seventh Example of the present disclosure as shown in FIG. 12 and FIG. 13 is substantially the same as the display device according to First Example of the present disclosure as shown in FIG. 4 through FIG. 6 except a configuration of the cathode contact part CAC, the first gap structure GS1, and the second gap structure GS2. The same components are denoted by the same reference numerals and the description thereof may be omitted.

Referring to FIG. 12 and FIG. 13, the gate line GL may intersect the first to fourth data lines DL1 to DL4 to define the first to fourth sub-pixels SPn1 to SPn4 in the display device according to Seventh Example of the present disclosure.

Each of the first to fourth sub-pixels SPn1 to SPn4 may include two emission areas EMA1 and EMA2, i.e., the first emission area EMA1 and the second emission area EMA2, and one transmission area TA.

Meanwhile, as described above, the cathode power line EVSS may be disposed to apply a low-potential voltage to the second electrode CAT.

The cathode power line EVSS may be electrically connected to the cathode connection line 139 through the contact hole CH. The cathode connection line 139 may extend to the transmission area TA. The cathode connection line 139 may be disposed on a source/drain wiring layer.

For example, a part of the cathode connection line 139 extending to the transmission area TA may form the cathode contact part CAC. Also, for example, the cathode contact part CAC like the cathode power line EVSS may be disposed in a direction perpendicular to the cathode connection line 139, but is not limited thereto.

Further, the second electrode CAT may extend to the transmission area TA and may be electrically connected to the upper surface of the cathode contact part CAC exposed through the cathode contact hole CH_2. The cathode contact part CAC may be disposed on the source/drain wiring layer.

Meanwhile, in Seventh Example of the present disclosure, a pair of first gap structures GS1 are provided on both sides of the cathode contact part CAC. Also, the second gap structure GS2 is provided on the encapsulation substrate 140 facing the first gap structures GS1.

For example, the first gap structure GS1 composed of an overcoating layer pattern 765′, a bank layer pattern 780′, and a spacer 795 may be provided on each of the both sides of the cathode contact part CAC.

For example, the spacer 795 may be made of the same transparent organic material as the spacer on the bank layer 180. For example, the spacer 795 may be made of one of polyimide, photo acryl, and benzocyclobutene (BCB), which are transparent organic materials.

Further, the second gap structure GS2 in which the color filter and the black matrix are deposited may be disposed on the encapsulation substrate 140 facing the pair of first gap structures GS1.

For example, the second gap structure GS2 according to Seventh Example of the present disclosure may be composed of a black matrix pattern 745′ and a red color filter layer pattern 770R′ on the encapsulation substrate 140. However, the present disclosure is not limited thereto. A blue color filter layer pattern or a green color filter layer pattern may be used instead of the red color filter layer pattern 770R′. The blue color filter layer pattern or the green color filter layer pattern may be further deposited in addition to the red color filter layer pattern 770R′. The components to be included in the second gap structure GS2 may be determined by the height of the spacer 795 of the first gap structure GS1.

For example, the black matrix pattern 745′ may be disposed on the encapsulation substrate 140 so as to face the first gap structure GS1.

For example, the black matrix pattern 745′ may be prepared in the same process as the black matrix 145 and formed to have a greater thickness than the black matrix 145, but is not limited thereto.

For example, the red color filter layer pattern 770R′ may be deposited on the black matrix pattern 745′.

For example, the insulating layer 190 may be disposed on the encapsulation substrate 140 including the red color filter layer pattern 770R′. Also, the insulating layer 190 may be in contact with upper surfaces of the pair of first gap structures GS1.

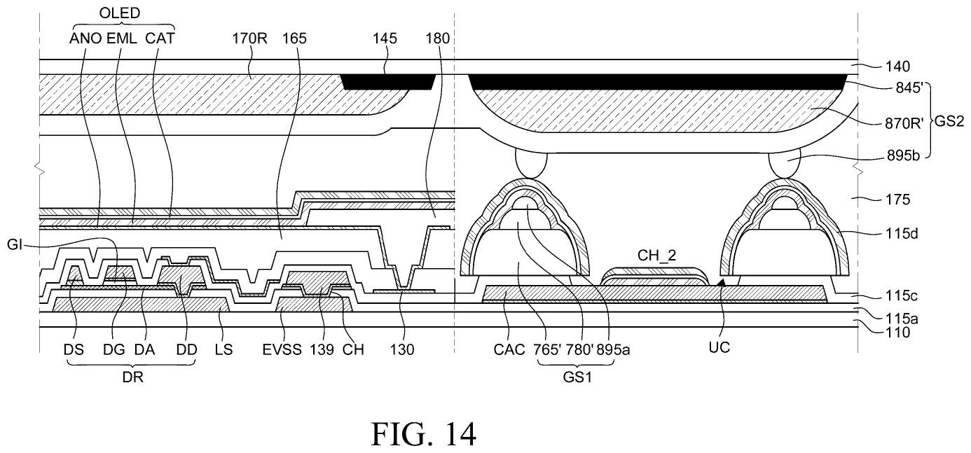

FIG. 14 is a cross-sectional view of a display device according to Eighth Example of the present disclosure.

The display device according to Eighth Example of the present disclosure as shown in FIG. 14 is substantially the same as the display device according to First Example of the present disclosure as shown in FIG. 4 through FIG. 6 except a configuration of the cathode contact part CAC, the first gap structure GS1, and the second gap structure GS2. The same components are denoted by the same reference numerals and the description thereof may be omitted.

FIG. 14 shows a cross-section of substantially the same part as FIG. 13. The left side of FIG. 14 shows a cross-section of a part of the first emission area EMA1 of the fourth sub-pixel SPn4. The right side of FIG. 14 shows a cross-section of a part of the transmission area TA of the fourth sub-pixel SPn4.

Referring to FIG. 14, as described above, the cathode power line EVSS may be disposed to apply a low-potential voltage to the second electrode CAT.

The cathode power line EVSS may be electrically connected to the cathode connection line 139 through the contact hole CH. The cathode connection line 139 may extend to the transmission area TA. The cathode connection line 139 may be disposed on a source/drain wiring layer.

For example, a part of the cathode connection line 139 extending to the transmission area TA may form the cathode contact part CAC. Also, for example, the cathode contact part CAC like the cathode power line EVSS may be disposed in the direction perpendicular to the cathode connection line 139, but is not limited thereto.

Further, the second electrode CAT may extend to the transmission area TA and may be electrically connected to the upper surface of the cathode contact part CAC exposed through the cathode contact hole CH_2. The cathode contact part CAC may be disposed on the source/drain wiring layer.

Meanwhile, in Eighth Example of the present disclosure, the pair of first gap structures GS1 are provided on both sides of the cathode contact part CAC. Also, the second gap structure GS2 is provided on the encapsulation substrate 140 facing the pair of first gap structures GS1.

For example, the first gap structure GS1 composed of the overcoating layer pattern 765′, the bank layer pattern 780′, and a first spacer 895a may be provided on each of the both sides of the cathode contact part CAC.

For example, the first spacer 895a may be made of the same transparent organic material as the spacer on the bank layer 180. For example, the first spacer 895a may be made of one of polyimide, photo acryl, and benzocyclobutene (BCB).

Further, the second gap structure GS2 in which the color filter and the black matrix are deposited may be disposed on the encapsulation substrate 140 facing the pair of first gap structures GS1.

For example, the second gap structure GS2 according to Eighth Example of the present disclosure may be composed of a black matrix pattern 845′ and a red color filter layer pattern 870R′ on the encapsulation substrate 140. However, the present disclosure is not limited thereto. A blue color filter layer pattern or a green color filter layer pattern may be used instead of the red color filter layer pattern 870R′. The blue color filter layer pattern or the green color filter layer pattern may be further deposited in addition to the red color filter layer pattern 870R′. The components to be included in the second gap structure GS2 may be determined by the height of the first spacer 895a of the first gap structure GS1.

For example, the black matrix pattern 845′ may be disposed on the encapsulation substrate 140 so as to face the first gap structure GS1.

For example, the black matrix pattern 845′ may be prepared in the same process as the black matrix 145 and formed to have the same thickness as the black matrix 145, but is not limited thereto.

For example, the red color filter layer pattern 870R′ may be deposited on the black matrix pattern 845′.

For example, the insulating layer 190 may be disposed on the encapsulation substrate 140 including the red color filter layer pattern 870R′. Also, for example, a pair of second spacers 895b may be disposed on the insulating layer 190 facing the pair of first gap structures GS1. The pair of second spacers 895b may be in contact with the upper surfaces of the pair of first gap structures GS1, respectively. For example, the second spacers 895b may be made of one of polyimide, photo acryl, and benzocyclobutene (BCB).

For example, the second spacer 895b may be disposed to face the first spacer 895a.

As described above, in Eighth Example of the present disclosure unlike Seventh Example, the black matrix pattern 845′ has the same thickness as the black matrix 145. Thus, a predetermined cell gap can be implemented by further providing the second spacers 895b on the insulating layer 190.

The example embodiments of the present disclosure can also be described as follows:

According to an aspect of the present disclosure, there is provided a display device. The display device includes a substrate including a plurality of sub-pixels, an encapsulation substrate bonded to the substrate in a state where an adhesive film is disposed on the substrate, a driving transistor disposed in the sub-pixel, an organic light emitting diode connected to the driving transistor, a cathode contact part connected to the organic light emitting diode and configured to apply a low-potential voltage, a first gap structure disposed over the cathode contact part and a second gap structure disposed over the encapsulation substrate so as to face the first gap structure.

The sub-pixel may include a transmission area and an emission area.

The plurality of sub-pixels may be defined by a data line, a sensing line, a power line, and a gate line intersecting one another, and the sub-pixel may further include a switching transistor, a sensing transistor, and a capacitor.

The emission area may include a first emission area overlapping the driving transistor and a second emission area overlapping the switching transistor and the sensing transistor.

The display device may further comprise a cathode power line disposed in parallel with the data line, the cathode power line may be electrically connected to a cathode connection line through a contact hole.

The cathode connection line may extend to the transmission area and may form the cathode contact part.

The first gap structure may be composed of at least one insulating layer pattern.

The insulating layer pattern may include at least an overcoating layer pattern and a bank layer pattern.

An undercut may be provided under the first gap structure, and the overcoating layer pattern and the bank layer pattern may have an island shape.

The second gap structure may be composed of a black matrix pattern and at least one color filter layer pattern deposited on the black matrix pattern.

The color filter layer pattern may include a red color filter layer pattern, a blue color filter layer pattern, and a green color filter layer pattern.

The black matrix pattern may have a greater thickness than a black matrix disposed on the encapsulation substrate.

The black matrix pattern may include a first concave region prepared by removing a predetermined portion facing the first gap structure, and the color filter layer pattern may be disposed on the black matrix pattern to fill in the first concave region.

A portion of the color filter layer pattern corresponding to the first concave region may be dented to form a second concave region having a smaller size than the first concave region.

The display device may further comprise an insulating layer disposed on the color filter layer pattern, a portion of the insulating layer corresponding to the second concave region may be dented to form a concave region having a smaller size than the second concave region.

An upper end of the first gap structure may be inserted into the concave region.

The black matrix pattern may have a reverse taper.

The display device may further comprise a spacer disposed on the insulating layer around an upper end of the first gap structure.

The first gap structure may further include a spacer disposed on the insulating layer pattern.

The display device may further comprise a second spacer disposed on the insulating layer facing the first gap structure, the first gap structure may further include a first spacer disposed on the insulating layer pattern.

The cathode connection line may extend to the transmission area and forms the cathode contact part, and the cathode contact part may be disposed in a direction perpendicular to the cathode connection line.

At least a pair of first gap structures may be provided on both sides of the cathode contact part.

The second gap structure may be composed of a black matrix pattern and at least one color filter layer pattern deposited on the black matrix pattern.

The first gap structure may further include a spacer disposed on the insulating layer pattern.

The display device may further comprise an insulating layer disposed on the color filter layer pattern and a second spacer disposed on the insulating layer facing the first gap structure, and the first gap structure may further include a first spacer disposed on the insulating layer pattern.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a plurality of sub-pixels;
an encapsulation substrate bonded to the substrate in a state where an adhesive film is disposed on the substrate;
a driving transistor disposed in each sub-pixel of the plurality of sub-pixels;
an organic light emitting diode connected to the driving transistor;
a cathode contact part connected to the organic light emitting diode and configured to receive a low-potential voltage;
a first gap structure disposed over the cathode contact part; and
a second gap structure disposed over the encapsulation substrate and facing the first gap structure.

2. The display device according to claim 1, wherein the sub-pixel includes a transmission area and an emission area.

3. The display device according to claim 2, wherein the plurality of sub-pixels each is coupled to a data line, a sensing line, a power line, and a gate line intersecting one another, and
wherein the sub-pixel further includes a switching transistor, a sensing transistor, and a capacitor.

4. The display device according to claim 3, wherein the emission area includes a first emission area overlapping the driving transistor and a second emission area overlapping the switching transistor and the sensing transistor.

5. The display device according to claim 3, further comprising:
a cathode power line disposed in parallel with the data line,
wherein the cathode power line is electrically connected to a cathode connection line through a contact hole.

6. The display device according to claim 5, wherein the cathode connection line extends to the transmission area and forms the cathode contact part.

7. The display device according to claim 5, wherein the first gap structure includes at least one insulating layer pattern.

8. The display device according to claim 7, wherein the insulating layer pattern includes at least an overcoating layer pattern and a bank layer pattern.

9. The display device according to claim 8, wherein an undercut is provided under the first gap structure, and the overcoating layer pattern and the bank layer pattern each have an island shape.

10. The display device according to claim 7, wherein the second gap structure includes:
a black matrix pattern; and
at least one color filter layer pattern deposited on the black matrix pattern.

11. The display device according to claim 10, wherein the color filter layer pattern includes a red color filter layer pattern, a blue color filter layer pattern, and a green color filter layer pattern.

12. The display device according to claim 10, wherein the black matrix pattern of the second gap structure has a greater thickness than a black matrix disposed on the encapsulation substrate.

13. The display device according to claim 10, wherein the black matrix pattern includes a first concave region prepared by removing a predetermined portion facing the first gap structure, and
wherein the color filter layer pattern is disposed on the black matrix pattern to fill in the first concave region.

14. The display device according to claim 13, wherein a portion of the color filter layer pattern corresponding to the first concave region is dented to form a second concave region having a smaller size than the first concave region.

15. The display device according to claim 14, further comprising:
an insulating layer disposed on the color filter layer pattern,
wherein a portion of the insulating layer corresponding to the second concave region is dented to form a concave region having a smaller size than the second concave region.

16. The display device according to claim 15, wherein an upper end of the first gap structure is inserted into the concave region.

17. The display device according to claim 10, wherein the black matrix pattern has a reverse taper.

18. The display device according to claim 15, further comprising:
a first spacer disposed on the insulating layer around an upper end of the first gap structure.

19. The display device according to claim 18, wherein the first gap structure further includes a spacer portion disposed on the insulating layer pattern.

20. The display device according to claim 18, further comprising:
a second spacer disposed on the insulating layer facing the first gap structure,
wherein the first gap structure further includes a spacer portion disposed on the insulating layer pattern.

21. The display device according to claim 7, wherein the cathode connection line extends to the transmission area and forms the cathode contact part, and
wherein the cathode contact part is disposed in a direction perpendicular to the cathode connection line.

22. The display device according to claim 21, wherein at least a pair of first gap structures are provided on both sides of the cathode contact part.

23. The display device according to claim 21, wherein the second gap structure includes:
a black matrix pattern; and
at least one color filter layer pattern deposited on the black matrix pattern.

24. The display device according to claim 23, wherein the first gap structure further includes a spacer disposed on the insulating layer pattern.

25. The display device according to claim 23, further comprising:
an insulating layer disposed on the color filter layer pattern; and
a first spacer disposed on the insulating layer facing the first gap structure, and
wherein the first gap structure further includes a second spacer disposed on the insulating layer pattern.
